(19) United States
(12) Patent Application Publication
(10) Pub. No.: US 2019/0154741 A1
(43) Pub. Date: May 23, 2019

(54) Electric Vehicle Disaggregation and Detection in Whole-House Consumption Signals

(71) Applicants: Rohit Aggarwal, San Jose, CA (US); Abhay Gupta, Cupertino, CA (US); Vivek Garud, Cupertino, CA (US)

(72) Inventors: Rohit Aggarwal, San Jose, CA (US); Abhay Gupta, Cupertino, CA (US); Vivek Garud, Cupertino, CA (US)

(21) Appl. No.: 16/259,748

(22) Filed: Jan. 28, 2019

Related U.S. Application Data
(63) Continuation-in-part of application No. 14/612,499, filed on Feb. 3, 2015, now Pat. No. 10,191,096.

(51) Int. Cl. G01R 21/133; B60L 53/66

(52) U.S. Cl. CPC G01R 21/133; B60L 53/665

(57) ABSTRACT

The present invention is directed to systems and methods of disaggregating and detecting energy usage associated with electric vehicle charging from a whole-house consumption signal. In general, methods of the present invention may include: a method of electronically detecting and disaggregating a consumption signal associated with the charging of an electric vehicle from a whole-house profile, comprising: identifying by an electronic processor potential interval candidates of electric vehicle charging; determining by the electronic processor intervals associated with the charging of an electric vehicle, based at least in part on evaluating each potential interval candidate against factors including amplitude, duration, and time-of-day; and accounting by the electronic processor for feedback of any incorrectly detected signals.

### RELATED APPLICATIONS

The present application is a continuation-in-part of, and claims priority to, U.S. patent application Ser. No. 14/612,499, filed on 3 Feb. 2015, which is incorporated by reference herein in its entirety.

### BACKGROUND OF THE INVENTION

In general, the present invention is directed to systems and methods of detecting energy usage associated with charging an electric vehicle. More specifically, the present invention is directed to systems and methods of detecting and disaggregating charging signals associated with electric vehicles from a whole-house profile or consumption signal.

Recent studies show that electric vehicles (EV) have emerged as a major part of the smart grid. While the adoption of EV's may be an important step forward towards a cleaner environment and energy independent society, an average EV owner may expect his or her electricity bill to rise considerably due to the frequent charging required. Accordingly, it is desirable to provide EV users with an interface to better understand the energy costs of EV ownership, as well as to provide additional information and/or features based upon such energy usage.

### SUMMARY OF THE INVENTION

Some aspects in accordance with some embodiments of the present invention may include a method of electronically detecting and disaggregating a consumption signal associated with the charging of an electric vehicle from a whole-house profile, comprising: identifying by an electronic processor potential interval candidates of electric vehicle charging; determining by the electronic processor intervals associated with the charging of an electric vehicle, based at least in part on evaluating each potential interval candidate against factors including amplitude, duration, and time-of-day; and accounting by the electronic processor for feedback of any incorrectly detected signals.

Other aspects in accordance with some embodiments of the present invention may include a method of electronically detecting and disaggregating a consumption signal associated with the charging of an electric vehicle from a whole-house profile, comprising: identifying by an electronic processor potential interval candidates of electric vehicle charging; and determining by the electronic processor intervals associated with the charging of an electric vehicle, based at least in part on evaluating each potential interval candidate.

Other aspects in accordance with some embodiments of the present invention may include a method of electronically detecting and disaggregating a consumption signal associated with the charging of an electric vehicle from a whole-house profile, comprising: identifying by an electronic processor, potential interval candidates of electric vehicle charging using sliding windows of various sizes and optimization techniques including dynamic programming, alpha-beta pruning, Bayesian/probabilistic models, and/or branch-and-bound algorithms; determining by the electronic processor intervals associated with the charging of an electric vehicle, based at least in part on evaluating each potential interval candidate by fitting each potential interval candidate shape with one or more parametric models; and accounting by the electronic processor for feedback of any incorrectly detected signals.

Other aspects in accordance with some embodiments of the present invention may include a method of electronically detecting and disaggregating a consumption signal associated with the partial charging of an electric vehicle from a whole-house profile, comprising: identifying by an electronic processor potential interval candidates of electric vehicle charging, based at least in part upon features characteristic of previously determined electric vehicle charging; determining by the electronic processor intervals associated with the charging of an electric vehicle, based at least in part on evaluating each potential interval candidate; and accounting by the electronic processor for feedback of any incorrectly detected signals.

Still other aspects in accordance with some embodiments of the present invention may include a method of electronically detecting and disaggregating consumption signals associated with charging electric vehicles, comprising: identifying potential interval candidates of electric vehicle charging using sliding windows of various sizes and optimization techniques including dynamic programming, alpha-beta pruning, Bayesian/probabilistic models, and/or branch-and-bound algorithms; determining intervals associated with the charging of an electric vehicle, based at least in part on evaluating each potential interval candidate by fitting each potential interval candidate shape with one or more parametric models; accounting for feedback of any incorrectly detected signals; determining energy load associated with charging of electric vehicles in a specified geographic area or energy grid section; and providing information regarding additional energy that may be required to be provided to the specified geographic area or energy grid section from the utility in response to electric vehicle charging.

These and other aspects will become apparent from the following description of the invention taken in conjunction with the following drawings, although variations and modifications may be affected without departing from the scope of the novel concepts of the invention.

### BRIEF DESCRIPTION OF THE FIGURES

The present invention can be more fully understood by reading the following detailed description together with the accompanying drawings, in which like reference indicators are used to designate like elements. The accompanying figures depict certain illustrative embodiments and may aid in understanding the following detailed description. Before any embodiment of the invention is explained in detail, it is to be understood that the invention is not limited in its application to the details of construction and the arrangements of components set forth in the following description or illustrated in the drawings. The embodiments depicted are to be understood as exemplary and in no way limiting of the overall scope of the invention. Also, it is to be understood that the phraseology and terminology used herein is for the purpose of description and should not be regarded as limiting. The detailed description will make reference to the following figures, in which:

FIG. 1 illustrates an exemplary flow for disaggregating data related to a large-capacity electric vehicle, in accordance with some embodiments of the present invention.

FIG. 2 illustrates an exemplary flow for disaggregating data related to a small-capacity electric vehicle, in accordance with some embodiments of the present invention.

FIG. 3 illustrates an exemplary charging signal from a large-capacity electric vehicle, in accordance with some embodiments of the present invention.

FIG. 4 depicts an exemplary interval candidate search process, in accordance with some embodiments of the present invention.

FIG. 5 illustrates an exemplary whole-house profile with a detected electric vehicle charging session, in accordance with some embodiments of the present invention.

FIG. 6 illustrates an exemplary whole house profile with detected electric vehicle charging sessions, in accordance with some embodiments of the present invention.

FIG. 7 illustrates an exemplary signal associated with charging a small-capacity electric vehicle, in accordance with some embodiments of the present invention.

FIGS. 8A-8G depict exemplary signals associated with electric vehicle charging patterns, in accordance with some embodiments of the present invention.

FIG. 9 depicts an illustration of a return on investment (ROI) tool to determine possible savings for a customer available if the customer were to purchase an electric vehicle.

FIG. 10 depicts an illustration a ROI tool that may be used by a utility to determine EV based energy consumption in a region.

FIG. 11 illustrates an exemplary geographic heat map illustrating exemplary electric vehicle charging loads in different parts of a geographic region, in accordance with some embodiments of the present invention.

Before any embodiment of the invention is explained in detail, it is to be understood that the present invention is not limited in its application to the details of construction and the arrangements of components set forth in the following description or illustrated in the drawings. The present invention is capable of other embodiments and of being practiced or being carried out in various ways. Also, it is to be understood that the phraseology and terminology used herein is for the purpose of description and should not be regarded as limiting.

### DETAILED DESCRIPTION OF THE INVENTION

The matters exemplified in this description are provided to assist in a comprehensive understanding of various exemplary embodiments disclosed with reference to the accompanying figures. Accordingly, those of ordinary skill in the art will recognize that various changes and modifications of the exemplary embodiments described herein can be made without departing from the spirit and scope of the claimed invention. Descriptions of well-known functions and constructions are omitted for clarity and conciseness. Moreover, as used herein, the singular may be interpreted in the plural, and alternately, any term in the plural may be interpreted to be in the singular.

In general, the present invention is directed to systems and methods of detecting energy usage associated with charging an electric vehicle. More specifically, the present invention is directed to systems and methods of detecting and disaggregating charging signals associated with electric vehicles from a whole-house profile or consumption signal. A whole-house profile or consumption signal may be obtained by any suitable method. For example, such information may be collected utilizing a current (CT) clamp, an infrared (IR) sensor, communicating smart meters, an advanced metering infrastructure (AMI) interface, etc.

Note that data resolution from different sources may vary. In order to provide for an accurate disaggregation, data resolution may range from approximately one (1) second to several minutes. In addition to the electrical information of the whole-house profile, non-electrical information may also be utilized in disaggregation processes. For example, weather information (such as, but not limited to, temperature, cloud-cover, etc.) may be considered.

In general, EV's have distinctive charging signatures. In addition to consuming large contiguous blocks of energy, some EVs may exhibit a clear pattern of sloping decay toward the end of charging. This sloping decay is due at least in part to electrochemical properties of battery cells (lithium ion based, or otherwise) used in EVs. As batteries approach a full 100% charge, internal resistance of the battery cells may increase, thereby at least in part leading to lower power consumption.

Moreover, some chargers for EVs may employ a “step charging” method, in which a voltage held across the battery cells may be gradually decreased. Such methods further contribute to the decreasing charging signature.

Note that the type of EV—and the capacity of such EV—may alter the charging signature. For example, large capacity EVs (such as, but not limited to the Tesla Model S) may have the distinctive charging pattern discussed above. In contrast, small capacity EVs (including but not limited to the plug-in Toyota Prius) may have a less distinctive box-shaped signal. Although a box-shaped signal stemming from a low-capacity EV pattern may be simpler to detect simpler, care must be taken to disambiguate the EV signal from other appliances with a similar long-running, box-shaped signatures.

Due to variances in detecting large-capacity EV charging signals from small-capacity EV charging signals, each will be addressed in turn below.

### Large Capacity EV

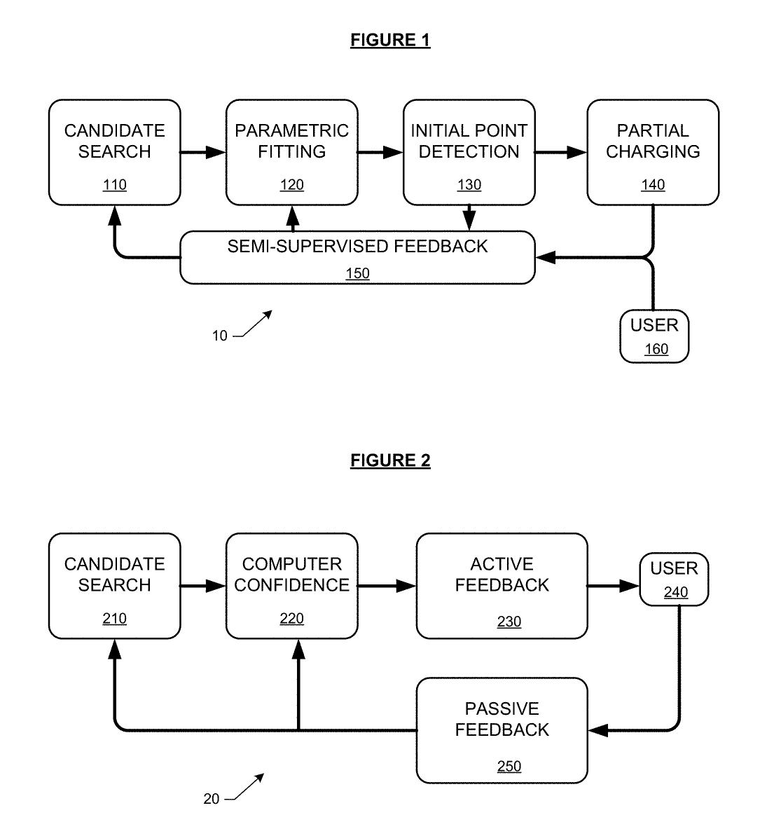

With reference to FIG. 1, an exemplary flow 10 for disaggregating data related to a large-capacity electric vehicle, in accordance with some embodiments of the present invention will now be discussed.

In general, systems and methods in accordance with the present invention make use of patterns that may be distinctive of an EV charging session. Such systems and methods may provide accurate event detection of EV signals in a large and noisy whole-house consumption signal. Moreover, successful detections of full charging sessions—and information or characteristics gleaned therefrom—may be leveraged to assist in identifying partial charging sessions, which may have otherwise been difficult to distinguish.

At 110, a candidate search for potential interval candidates may be performed. Such candidate search may look for signals that may indicate EV charging. For example, a candidate may search for long and decreasing patterns, or may search for other patterns that are associated with EV charging. In the case of long and decreasing patterns, an approach of identification may be to use sliding windows of varying sizes. In order to reduce run-time and memory usage, optimization techniques including, but not restricted to, dynamic programming, alpha-beta pruning and branch-and-bound may be utilized.

At 120, each potential identified candidate may be evaluated. Each candidate shape may be fit with parametric models, including but not limited to, log-linear models. Each model may provide a goodness-of-fit confidence, and an ensemble of models may accordingly produce a strong likelihood as to whether the candidate passes the detection, and likely represents charging of a large-capacity EV.

At 130, the initial point of charging (e.g., when charging starts) may be determined. This may be accomplished by scanning the data stream for upward transitions and using signal processing techniques such as smoothing, filtering and change-point detection. Appropriate “begin” candidates (or initial points) may be chosen. Accordingly, the EV signature may be located amidst the whole-house profile.

At 140, partial charging circumstances (e.g., where a full EV charging signature may not be present, or where the downward sloping signature may not be detected) may be accounted for by leveraging prior detections. Features, such as but not limited to amplitude, duration, and/or time-of-day may be extracted from past charging signatures, and then used to classify partial charging signatures. Note that the user 160 may provide input in the feedback loop 150. Such user feedback may increase the accuracy of the detection of EV charging signals.

Using prior detections and/or user-provided ground truth or input, the parameters in noted above pertaining to steps 110, 120, and 130 may be adjusted at 150 (semi-supervised feedback) to correct any incorrectly detected signals. Note that while semi-supervised techniques are illustrated in FIG. 1, it is contemplated that supervised techniques may also be applied.

### Proposed Solution Small-Capacity EV

With reference to FIG. 2, an exemplary flow 20 for disaggregating data related to a small-capacity electric vehicle, in accordance with some embodiments of the present invention will now be discussed.

The detection of small-capacity EV charging may be particularly difficult. In general, the charging signal of a small-capacity EV may be somewhat similar to several appliances that may be present within a home (for example, a sump-pump, pool pump, etc.). However, by utilizing user feedback systems and methods in accordance with the present invention may be utilized to detect the EV pattern non-intrusively and collaboratively with the user.

As noted above, small-capacity EVs tend to exhibit a box-shaped charging pattern. At 210, potential interval candidates may be searched. In general, candidates that exhibit a box-shaped pattern—a sharp upward transition with a corresponding downward transition—may be identified.

At 220, each candidate may be evaluated. For example, for each candidate a confidence level may be computed, based at least in part on a set of features including, but not restricted to, amplitude, duration and time of day. As will be discussed in more detail below, both active and passive feedback 230, 250 may also be considered in determining confidence levels and identifying instances of low-capacity EV charging.

Active feedback 230 may also be sought. For example, the identified candidates with high confidence may be submitted to the user 240, requesting feedback and/or confirmation of proper identification. Such request and receipt of feedback may be communicated in any number of methods. For example, such communications may be made through a website, web portal, application, software, mobile app, and/or other means. Feedback received from the user may be stored in the system and applied to future detections.

At 250 passive feedback may be obtained. For example, a user may provide general passive information about his or her home. Such information may include a profile of appliances within the home, as well as detailed information about the small-capacity EV. In this manner, the energy usage patterns of existing appliances (such as a pool pump or sump pump) may be differentiated from the EV.

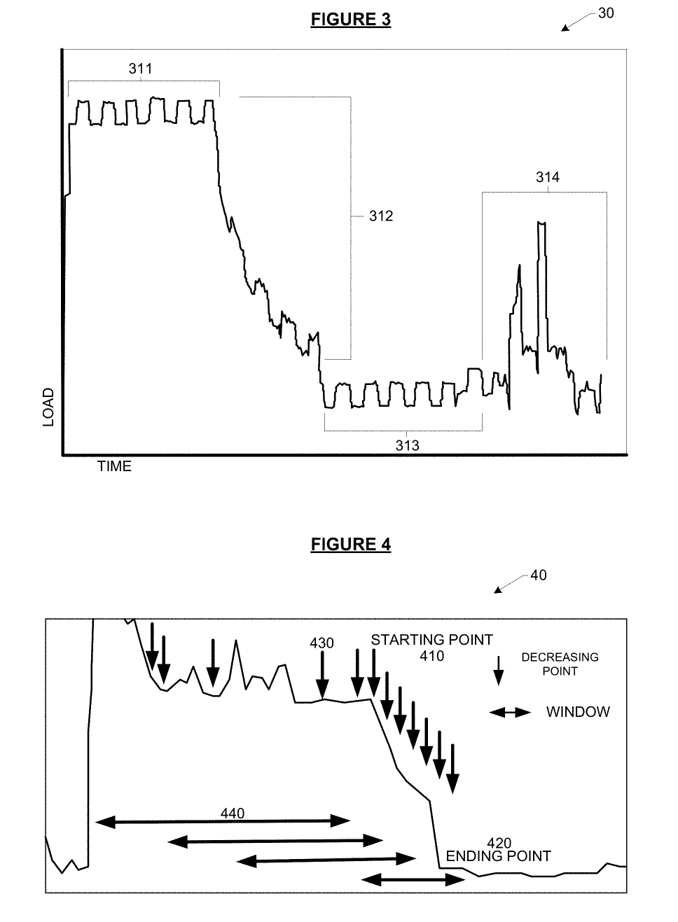

With reference to FIG. 3, an exemplary charging signal 30 from a large-capacity electric vehicle, in accordance with some embodiments of the present invention, will now be discussed. As noted above, large-capacity EVs tend to consume large contiguous blocks of energy, followed by a sloping decay near the end of charging. The portion of the signal denoted at 311 indicates the large contiguous block of energy required by the EV charging. Note that this energy usage is in combination with other energy usage within the home. At 312 the sloping pattern of decay can be identified. At 313, a baseload energy usage for a home may be seen. For example, the repeating block pattern may be due to appliances within the home, such as cycling refrigerators, pool pumps, HVAC units, etc. At 314 a larger energy draw is exhibited. Note the differences, however, between the energy draw at 314 and the identified EV charging pattern exhibited at 311 and 312.

With reference to FIG. 4, an exemplary interval candidate search process 40, in accordance with some embodiments of the present invention will now be discussed. As discussed, a candidate search may be performed using a sliding window approach. In general, sliding windows 440 of various sizes may be used to identify decreasing points 430. Decreasing patterns of decreasing points may then by identified, from which a starting point 410 and an ending point 420 may be determined.

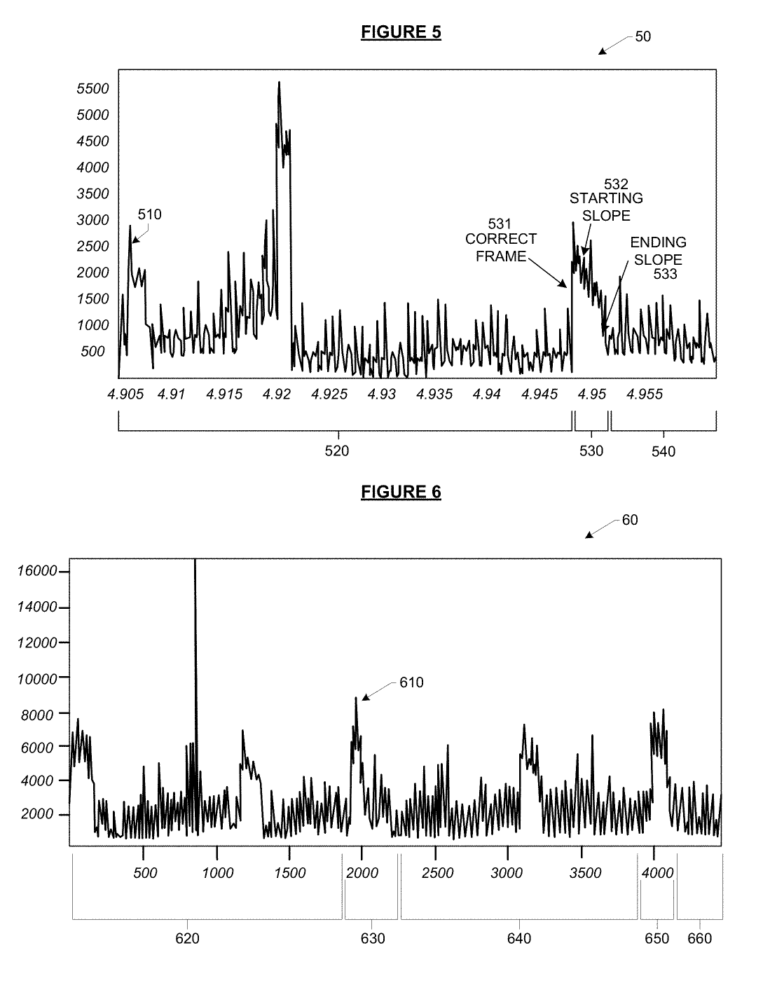

With reference to FIG. 5, an exemplary whole-house profile 510 with a detected electric vehicle charging session, in accordance with some embodiments of the present invention will now be discussed. It can be seen that profile 510 reflects varying energy usage from a user home. The portion of the signal denoted at 520 may represent general household usage, which may include some peak loads and cyclical energy usages. At 530, an EV charging session may be identified. At 531 the correct frame may be determined (the start of the charging session). This may be obtained from working backwards after identifying the decreasing or decaying slope, evident between starting slope point 532 and ending slope point 533. Note that after the EV charging session is completed, the general energy loads of the household continue at 540.

With reference to FIG. 6, an exemplary whole house profile with detected electric vehicle charging sessions, in accordance with some embodiments of the present invention, will now be discussed. A whole house profile 610 is seen, illustrating the varying energy uses of a household. Using the systems and methods as discussed above, two (2) different EV charging sessions may be identified from the overall whole house profile 610. Specifically, at 630 and 650, decreasing and decaying energy usage that matches the characteristics of EV charging may be identified. Such peak uses may be characteristically different and distinguishable from peak uses at 620, 640, or 650. Using the present invention, EV charging may accordingly be accurately disaggregated from the relatively noisy, whole-house profile.

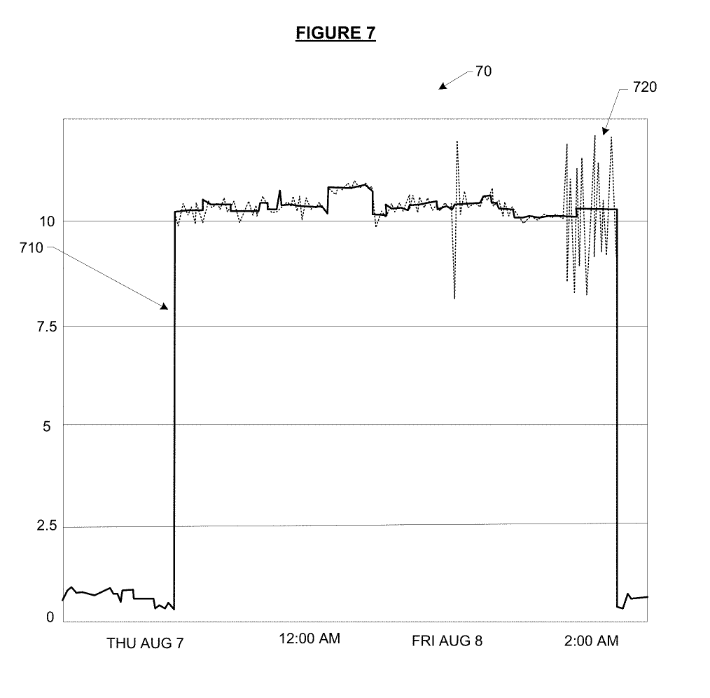

With reference to FIG. 7, illustrates an exemplary signal 70 associated with charging a small-capacity electric vehicle, in accordance with some embodiments of the present invention will now be discussed. The signal may exhibit a general box-shaped charging profile 710. Note that the overall profile may vary with spike energy uses 720 but may be smoothed to show the characteristic box profile at 710.

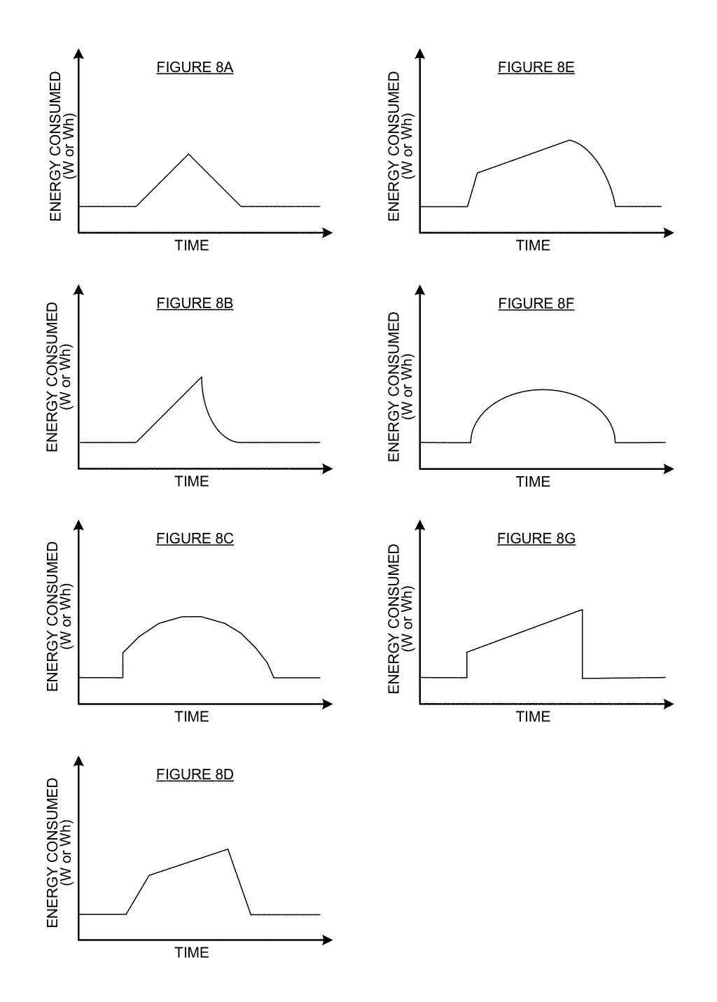

With the advent of EV charging technology, typical box-shaped EV charging patterns may be replaced by other types of charging patterns (such as, triangle, trapezoid, quadrilateral, part-quadrilateral and part-slow-decay, etc). FIGS. 8A-G sets forth some of these exemplary patterns. In detection of such patterns, the same methodology used for detection of box-shaped pattern applies with the caveat that the features specific to the pattern changes from one pattern to another. Depending on the shape of the pattern, either all the steps in FIG. 1 and/or all the steps in FIG. 2 may apply.

FIGS. 8A-8G indicate a charging pattern, presented as a power/energy draw over time. FIG. 8A indicates a triangular pattern. FIG. 8B illustrates a wave-shaped charging pattern. FIG. 8C shows an exemplary stepped pattern, while FIG. 8D illustrates a trapezoidal shaped pattern. FIG. 8E indicates a partial trapezoidal charge with a sloping decline, while FIG. 8F shows a rounded humped charging pattern. FIG. 8F illustrates another trapezoidal charging patterns.

Note that FIGS. 8A-8G do not, and are not intended to, set forth all relevant and/or applicable charging patterns. Rather, these charging patterns are set forth to illustrate that the systems and methods of the present invention can be applied to different charging patterns, which may be associated with different EVs, and/or different types of batteries or charging protocols. The present invention is directed to the recognition of such charging patterns, as well as providing actionable information to consumers and/or utilities based thereon.

In addition to energy specific information (disaggregated energy usage of EV charging, cost and/or rate plans applied to each specific instance of charging), several other external data sources may be useful in providing the use with specific, actionable information. For example, real-time gas prices, specifics regarding each EV model, location of public (or otherwise available) charging stations and/or any associated cost therewith), etc., may be used by the present invention.

Using systems and methods discussed above, specific energy consumption (and cost) of each EV charging instance, beginning time, ending time, and power amplitude in each charge cycle may be determined. Several applications based on the disaggregated data and other information may be practiced. For example, by detecting the ending time of the last charge, a reminder to charge the EV may be sent to the user. Such reminder may include a note of the estimated miles left before the battery is exhausted. Moreover, if a user typically follows a predictable schedule, EV charging may be initiated just before use so that the EV will have a full—or “topped off” battery before use. Such “charge and go” processes may save battery life.

One application of the Electric Vehicle disaggregation approach discussed earlier is the detection of presence of electric vehicle in a home in a given period (day/week/month/year). There may be two ways of accomplishing this. One, the EV disaggregated data can be calculated as mentioned earlier, and then detection of EV is done in the given period (day/week/month/year). Second, all possible energy usage patterns (box shaped and otherwise) may be identified in the given period (day/week/month/year), and a machine learning model may be used to detect EV in that period. Note that such energy patterns may be calculated on a 15/30/60-minute granularity or even daily/weekly/monthly granularity. Furthermore, the size of such boxes can be as low as a single data-point. This application also provides insights into when the EV charging at the given home started vis-a-vis when did the customer purchase/acquire the EV.

Another application of EV disaggregated data is estimation of total and current battery capacity of EV and battery efficiency by analyzing the EV charging patterns over time. This information coupled with other user-specific information, such as geo-location, typical driving routes and timings, travel times, a user may be notified to charge their EV in advance so that they have sufficient charge available for their upcoming travel. Furthermore, the above information coupled with current traffic information may be useful in determining an efficient route. For example, if an EV uses regenerative charging, i.e., it charges the battery when brakes are applied, then in the event that the EV does not have sufficient charge for an upcoming travel, an efficient route might be proposed that avoids freeways.

Another application of EV disaggregated data is determining the type of charger (L1/L2/L3 or slow/fast or any other categorization) and the make/model of the EV.

Another application of EV disaggregated data is deriving insights about a user's EV usage behavior, such as daily miles driven, average battery charge left when the user charges EV, determining vehicle wear & tear based on cumulative miles driven, habits and lifestyle of a user, etc.

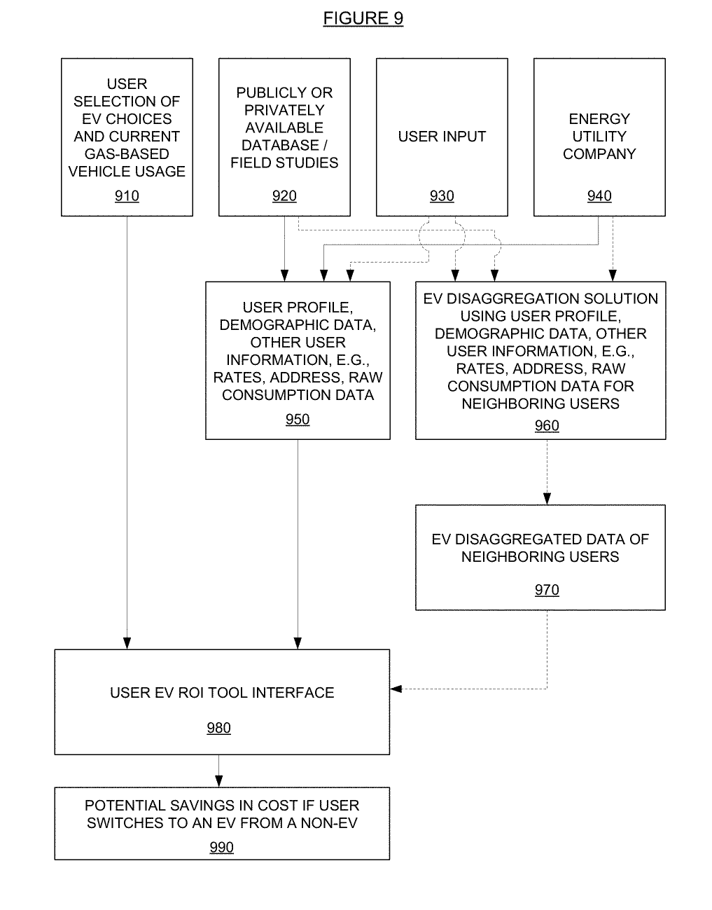

Another application of EV disaggregated data is providing an ROI tool to users who currently do not have an EV to estimate energy costs if they were to acquire an EV and compare against gas charges. FIG. 9 depicts an exemplary illustration of how such an ROI tool may utilize user profile & rate information available via energy-utility company/via publicly available information/via input, neighboring EV usage aggregations available from EV disaggregated data of neighboring EV-owners, and user-input about his/her EV choices and/or current gas-based vehicle usage to determine possible savings in costs.

With continued reference to FIG. 9, several inputs may be provided into an ROI tool. Note that dashed lines indicate alternative or possible connections. For example, a user selection of EV choices and the user's current gas-based (non-EV) vehicle and vehicle usage may be provided at 910. Publicly or privately available databases or field studies may be provided at 920. User input may be received at 930, and input received from a utility company be received at 940. Information from the publicly or privately available databases 920 may be provided combined with information received from the utility company 940 to form a user profile, demographic data, etc. at 950. This user profile 950 may be augmented by user input 930.

Each of publicly or privately available databases 920, user input 930, and/or energy utility company 940 may also provide information that may be used to formulate an EV disaggregation solution 960. The EV disaggregation solution 960 may be used to determined EV disaggregated data of neighboring users at 970. Each of the EV disaggregated data of neighboring users 970, the user profile 950, and/or the user selection of EV choices 910 may be provided to a user EV ROI tool interface 980, which may determine potential savings in cost if the user switches from a non-electric vehicle to an EV at 990.

Another application of EV disaggregated data is utility-grid optimization for utilities. Specifically, the disaggregated EV charging patterns across homes may be aggregated to optimize the utility grid for demand, publish non-intrusive field studies/white papers, and a tool may be provided to the energy utilities to design optimal energy tariffs based on EV charging patterns across homes.

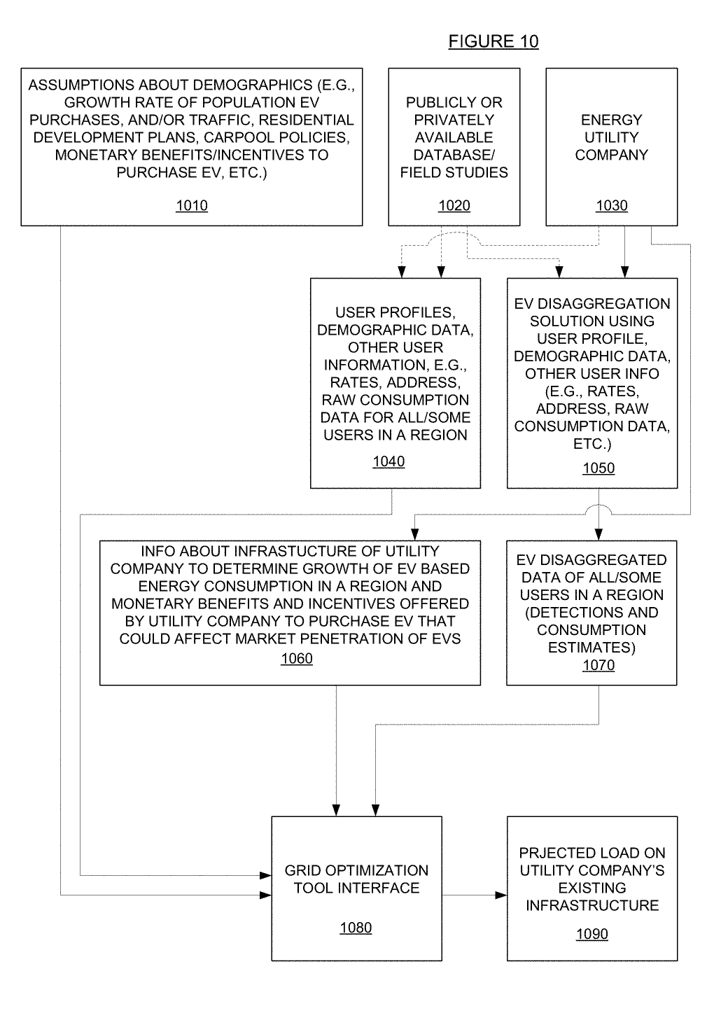

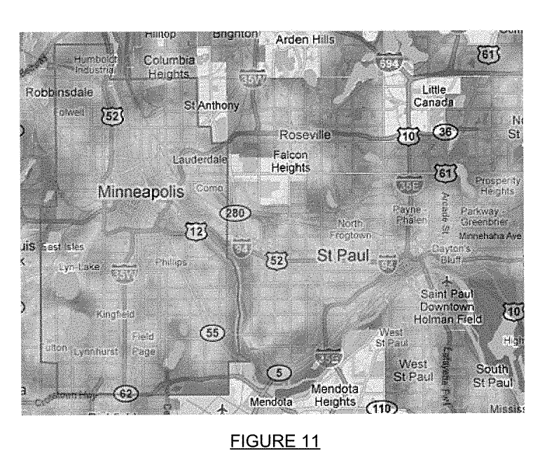

FIG. 10 shows an illustration of how such an ROI tool would utilize user profiles & rate information available via energy-utility company/via publicly available information, EV usage detections and consumption usage aggregations available from EV disaggregated data, assumptions about demographics such as population growth rate, residential development plans, EV purchases growth rate, traffic growth rate and carpool policies, monetary benefits & incentives offered by government/car company/utility company/other to purchase EV that could affect market penetration of EVs, and information about the utility company's current infrastructure to determine growth of EV based energy consumption in a region, and projected load on the existing infrastructure of the utility company.

With continued reference to FIG. 10, assumptions about demographics 1010 may be provided to a grid optimization tool interface 1080. Information from publicly or privately available databases and/or field studies 1020 may be provided to form both user profiles 1040, or to an EV disaggregation solution 1050. An energy utility company 1030 may provide information to the EV disaggregation solution 1050 and information about the utility infrastructure 1060, and may also provide information to the user profile 1040.

The EV disaggregation solution 1050 may assist in determining the EV disaggregated data of all or some users in a region 1070, which in turn may be provided to the grid optimization tool interface 1080. The information about the infrastructure of the utility 1060 may also be provided to the grid optimization tool interface 1080. The grid optimization tool interface 1080 may then determine, or assist in determining, a projected load on the utility company's existing infrastructure at 1090.

Furthermore, at a user-level, using the EV disaggregated data for a user, the utility may offer specialized rebates, rate-plans, and promotions to the user. For example, FIG. 11 illustrates a heat-map showing exemplary EV charging loads across a geographic region. This information may be desired by and useful to utilities in order to optimize energy provision, particularly at times with a large EV charging load.

In addition, disaggregated EV usage coupled with energy specific information (that may be obtained via disaggregation of the whole-house signal, or by associating a user's utility account (rates, etc.) may provide for additional applications. For example, disaggregation systems may be configured to notice and/or recognize any changes in the charging signature (for example, changes in the slope or duration or charging). Such changes—compared to historical patterns of charging—may indicate a particular battery status or issue. An alert may then be send to the user regarding any identified potential battery issues, including but not limited to battery degradation.

Moreover, by utilizing disaggregated data with the user's utility rates, the user may be informed regarding the actual value of using an EV by comparing the real time gas price versus EV charging electricity price. Such data may even take into account time-of-use rate plans that may be applicable to a specific user.

Depending on the additional costs of EV charging, the user may be informed of any different plans offered by an applicable utility that may be more cost effective. For example if the user is not in time-of-use (TOU) rate plan, a recommendation of beneficial rate plans may be provided. Similarly, if the user is in TOU rate plan, information regarding charging compared with time-of-day may be provided, thereby informing the user that if he or she charges the EV in non-peak demand hours, a certain savings may be obtained. This information may be conveyed to the user either through the interfaces discussed above, or even through direct communication such as mail, which may include a reminder of best times to charge (such as a sticker that may be placed in or on the vehicle or the home charging station). In this manner, the burden of charging EVs across a utility network may be shifted to non-peak hours, which may be both more economically advantageous to the user, and preferable by the utility.

Disaggregation information may be used to provide real-time alerts which may include information such as when charging starts, finished, and/or the current charging percent. Similarly, information regarding charging stations may be supplied to the user, including for example, a recommendation of nearest and most cost-effective charging stations and/or monetary savings that may be obtained from the use of such specific charging stations.

Moreover, information generalized for EV makes or models may also be provided to potential consumers of EVS, setting forth potential incentives of value based on gas price and green factors. Such information may present potential customers with estimated charging costs based on the local utility, current rate structures, etc. In this manner, a potential customer may be more educated as to the actual costs and benefits of owning an EV.

It will be understood that the specific embodiments of the present invention shown and described herein are exemplary only. Numerous variations, changes, substitutions and equivalents will now occur to those skilled in the art without departing from the spirit and scope of the invention. Similarly, the specific shapes shown in the appended figures and discussed above may be varied without deviating from the functionality claimed in the present invention. Accordingly, it is intended that all subject matter described herein and shown in the accompanying drawings be regarded as illustrative only, and not in a limiting sense, and that the scope of the invention will be solely determined by the appended claims.

What is claimed is:

1. A method of electronically detecting and disaggregating a consumption signal associated with the charging of an electric vehicle from a whole-house profile, comprising:
identifying by an electronic processor potential interval candidates of electric vehicle charging;
determining by the electronic processor intervals associated with the charging of an electric vehicle, based at least in part on evaluating each potential interval candidate against factors including amplitude, duration, and time-of-day;
accounting by the electronic processor for feedback of any incorrectly detected signals.

2. The method of claim 1, further comprising:
determining certain household appliances within the home and disaggregating energy usage associated with such certain household appliances; and
wherein the step of determining intervals associated with the charging of an electric vehicle further comprises eliminating from potential interval candidates any candidate who have profiles associated with certain household appliances.

3. The method of claim 1, wherein certain household appliances within the home are determined based upon non-intrusive load monitoring.

4. The method of claim 1, wherein the certain household appliances may be selected from the group consisting of: refrigerator, pool pump, sump pump, and heating, ventilation, and air-conditioning (HVAC) unit.

5. The method of claim 1, wherein the identifying of potential interval candidates of electric vehicle charging is based at least in part on the shape of the energy usage pattern.

6. The method of claim 5, wherein the shape of the energy usage pattern comprises a box, triangle, quadrilateral, or hump.

7. The method of claim 1, wherein the identifying of potential interval candidates of electric vehicle charging is based at least in part on a daily or weekly energy usage spike.

8. The method of claim 1, further comprising: determining a power rating of a charger used to charge the electric vehicle.

9. The method of claim 1, further comprising: determining an estimation of total electric vehicle battery capacity, current electric vehicle battery capacity, and/or electric vehicle battery efficiency.

10. The method of claim 1, further comprising: determining a make and model of the electric vehicle based at least in part on the energy usage pattern.

11. The method of claim 1, further comprising: determining, base at least in part upon the energy use patterns, charging duration, and/or charging times: commute distances, driving patterns and/or habits associated with the use of the electric vehicle.

12. The method of claim 1, further comprising detecting an anomaly in the charging of the electric vehicle and notifying a user.

13. A method of electronically detecting and disaggregating a consumption signal associated with the charging of an electric vehicle from a whole-house profile, comprising:
identifying by an electronic processor potential interval candidates of electric vehicle charging;
determining by the electronic processor intervals associated with the charging of an electric vehicle, based at least in part on evaluating each potential interval candidate.

14. The method of claim 13, wherein identifying potential interval candidates further comprises using optimization techniques selected from the group consisting of: dynamic programming, alpha-beta pruning, Bayesian/probabilistic algorithms, and branch-and-bound algorithms.

15. The method of claim 13, wherein the evaluation of each potential interval candidate comprises fitting each potential interval candidate shape with one or more parametric models.

16. The method of claim 15, further comprising determining goodness-of-fit of each parametric model to determine if each potential interval candidate represents the charging of an electric vehicle.

17. A method of electronically detecting and disaggregating a consumption signal associated with the charging of an electric vehicle from a whole-house profile, comprising:
identifying by an electronic processor, potential interval candidates of electric vehicle charging using sliding windows of various sizes and optimization techniques including dynamic programming, alpha-beta pruning, Bayesian/probabilistic models, and/or branch-and-bound algorithms;
determining by the electronic processor intervals associated with the charging of an electric vehicle, based at least in part on evaluating each potential interval candidate by fitting each potential interval candidate shape with one or more parametric models; and
accounting by the electronic processor for feedback of any incorrectly detected signals.

18. a method of electronically detecting and disaggregating consumption signals associated with charging electric vehicles, comprising:
identifying potential interval candidates of electric vehicle charging;
determining intervals associated with the charging of an electric vehicle, based at least in part on evaluating each potential interval candidate by fitting each potential interval candidate shape with one or more parametric models;
determining energy load associated with charging of electric vehicles in a specified geographic area or energy grid section; and
determining a projected load for the existing infrastructure of a utility company.
